(19) United States
(12) Patent Application Publication
(10) Pub. No.: US 2014/0367859 A1
(43) Pub. Date: Dec. 18, 2014

(54) TIN-BASED WIREBOND STRUCTURES

(71) Applicant: Freescale Semiconductor, Inc., Austin, TX (US)

(72) Inventors: Burton J. Carpenter, Austin, TX (US); Leo M. Higgins, III, Austin, TX (US); Varughese Mathew, Austin, TX (US); Tu-Anh N. Tran, Austin, TX (US); Nhat D. Vo, Austin, TX (US)

(21) Appl. No.: 14/305,277

(22) Filed: Jun. 16, 2014

Related U.S. Application Data
(60) Provisional application No. 61/835,718, filed on Jun. 17, 2013.

(51) Int. Cl. H01L 23/00

(52) U.S. Cl. CPC H01L 24/08; H01L 24/48; H01L 2224/08502; H01L 2924/01029; H01L 2924/0105
USPC 257/762

(57) ABSTRACT

Tin-based wirebond structures and wirebonds formed thereon. In some embodiments, an electronic package includes a semiconductor die located over a substrate and a wire configured to couple a terminal of the semiconductor die to a bond pad on the substrate. A wire bond between the wire and the bond pad may include an amount of tin originated from a layer of tin alloy formed on the bond pad. In other embodiments, a wirebond structure may include a conductive layer and a layer of tin alloy located over a portion of the conductive layer. The layer of tin alloy may provide a wirebonding contact surface configured to receive a bond wire.

### CROSS REFERENCE TO RELATED APPLICATIONS

The present application claims priority to U.S. Provisional Patent Application No. 61/835,718 titled “TIN-BASED WIREBOND STRUCTURES” and filed on Jun. 17, 2013, the entirety of which is incorporated by reference herein.

### FIELD

This disclosure relates generally to semiconductors, and more specifically, to tin-based wirebond structures and wirebonds formed thereon.

### BACKGROUND

Some microelectronic device packages include wirebonds for providing electrical coupling between a package substrate and an encapsulated die. Typically, a wirebond includes a piece of wire that couples a terminal on the die to a pad on the substrate. Although the wire itself can be made of copper, the point of contact on the substrate's pad is not fabricated with bare copper due to its hardness, which makes it difficult to create a bond. Also, bare copper pads oxidize over time, making the resulting bonds unreliable. Thin coatings such as OSP (Organic Solderability Protectant) can be used to protect a copper pad from oxidizing, but this practice results in weak connections because the coating leaves organic residue between the wire and the pad.

To address some of these concerns, a substrate wirebonding structure may include a plating material that is deposited over a layer of copper to protect it from oxidation while enabling a metallurgical bond to be formed between the wire and the structure. Most widely used plating materials include gold. However, the use of gold on a package substrate presents a significant manufacturing cost.

### BRIEF DESCRIPTION OF THE DRAWINGS

The present invention(s) is/are illustrated by way of example and is/are not limited by the accompanying figures, in which like references indicate similar elements. Elements in the figures are illustrated for simplicity and clarity and have not necessarily been drawn to scale.

FIG. 1 is a cross-sectional view of an example of a microelectronic device package according to some embodiments.

FIG. 2 is a cross-sectional view of an example of a tin-based, wirebond structure according to some embodiments.

FIG. 3 is a cross-sectional view of an example of another tin-based, wirebond structure according to some embodiments.

FIG. 4 is a flowchart of a method for fabricating a tin-based, wirebond structure according to some embodiments.

FIG. 5 is a flowchart of a method for manufacturing a microelectronic device package according to some embodiments.

FIG. 6 is a diagram of an example of an electronic device having one or more electronic microelectronic device packages, according to some embodiments.

### DETAILED DESCRIPTION

Disclosed herein are tin-based, wirebond structures and wirebonds formed thereon. In some embodiments, a wirebond structure may include a layer of tin in its elemental form (Sn). As used herein, the term “elemental tin” refers to a material that has at least 99.9% tin by actual weight. In other embodiments, the tin layer may include a tin alloy. Additionally or alternatively, in some embodiments, the thickness of the tin layer may be 1.5 um or less. Additionally or alternatively, in some embodiments, the tin layer may exhibit a hardness of 8.0 HB or greater. In yet other embodiments, a barrier layer of another metal such as nickel (Ni) may be plated between a base metal layer (e.g., copper (Cu)) and the tin layer, for example to inhibit growth of intermetallic compounds (IMC). In many cases, the use of tin to create wirebond structures may provide for less expensive bonding surfaces because it reduces the need for conventional, costly metals (e.g., gold (Au)).

Generally speaking, it is desirable that a plating surface be easily applied during substrate fabrication, exhibit long term stability, and be bondable, such that wirebonds may be easily and consistently formed in high volume manufacturing using industry available wirebonding equipment and tools. “Bondability” is commonly characterized by the formation of a metallurgical joining of a wire metal to the substrate pad metal. In some embodiments, the bonding surface may be bondable for copper wire and its derivatives, such as palladium (Pd) coated copper wire—although other types of wires such as gold, silver (Ag) or aluminum (Al) may be used. Embodiments described herein may provide for a low cost substrate bonding surface that is stable, easily applied and bondable.

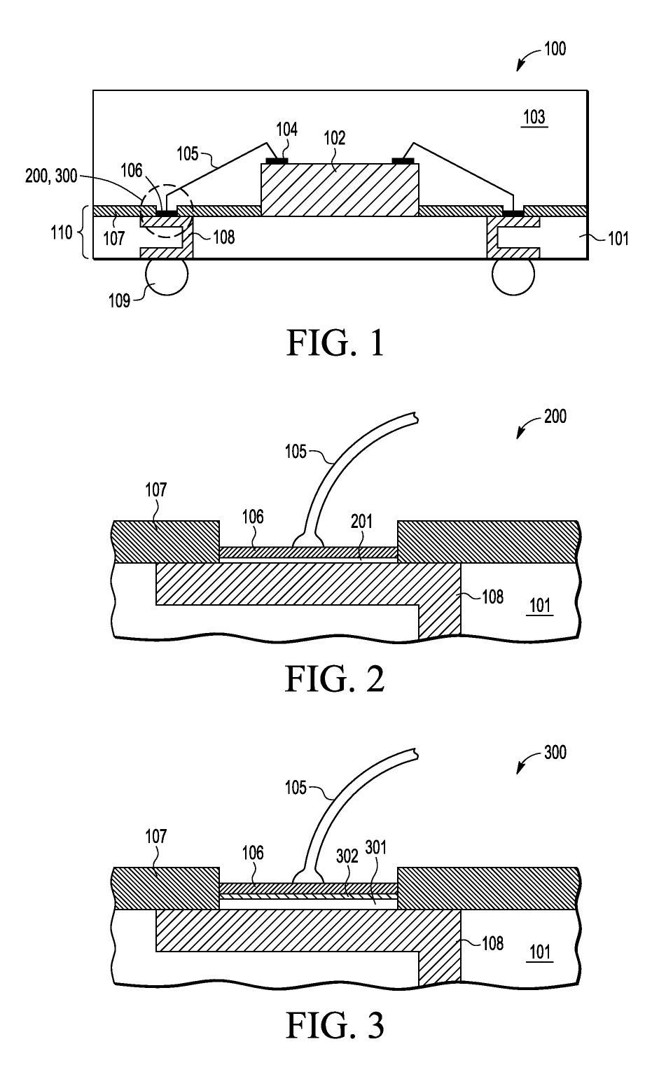

FIG. 1 is a cross-sectional view of an example of a microelectronic device package 100 according to some embodiments. As shown, package 100 includes semiconductor die 102 attached to package substrate 110 with an adhesive or tape (not shown), and covered by encapsulating material or encapsulant 103 (e.g., a mold compound, epoxy, etc.). Semiconductor die 102 includes a plurality of terminals, leads, or bond pads, one of which is indicated as bond pad 104.

Package substrate 110 includes dielectric layer 101, soldermask 107, and conductive interconnect 108. Package substrate 110 also includes a plurality of bond pads, one of which is shown as tin-based bond pad 106.

Wire 105 is surrounded by encapsulant 103, and it electrically couples bond pad 104 located on semiconductor die 102 to tin-based bond pad 106 located on package substrate 110. In the example shown, conductive interconnect 108 includes conductive layers, traces, and/or vias configured to electrically couple tin-based bond pad 106 to solder ball 109, thus providing external access to terminal 104 of die 102.

In various implementations, dielectric layer 101 may include any suitable dielectric material, such as epoxy laminates, ceramics, glass, polytetrafluoroethylene, other plastics, etc. Wire 105 may include any commonly used bonding wire including copper, gold, aluminum, palladium coated copper, silver etc. Conductive interconnect 108 may include any suitable conductive material, such as copper or the like. Soldermask 107 may include any suitable resist material such as polymer or epoxy, for example. Solder ball 109 may include any commonly used solder material such as, for example, a tin and silver alloy or the like.

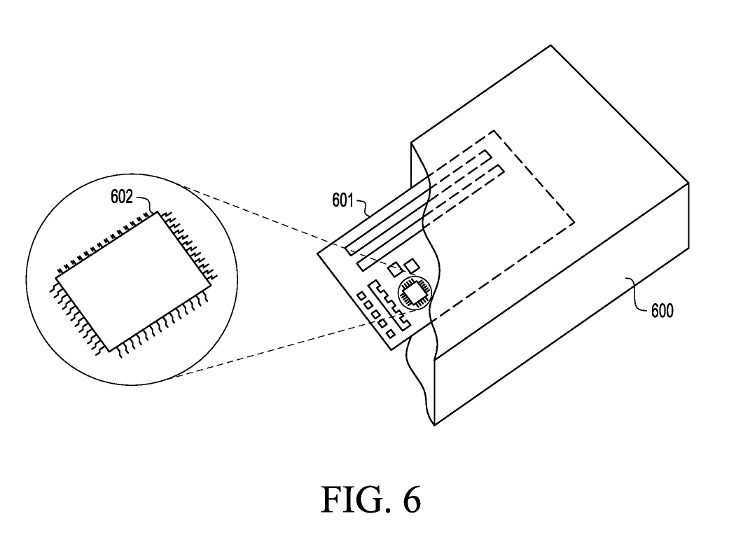

As explained in more detail in FIG. 6, die 102 may include one or more Integrated Circuits (ICs) and may be from a processed wafer that is singulated into individual die. The IC(s) may include devices such one or more processors, memories, logic, analog circuitries, MEMS devices, etc. In other embodiments, package 100 may include multiple die or include other types of microelectronic devices such as stand-alone inductors or capacitors. In other embodiments, package 100 may have other configurations and/or include other structure. For example, in some embodiments, microelectronic device package 100 may be a leaded package (e.g., quad-flat-pack or “QFP”) or leadless package (e.g., quad-flat no-leads or “QFN”).

Details 200, 300 showing tin-based bond pad 106, soldermask 107, and conductive interconnect 108 are shown in FIGS. 2 and 3. Particularly, FIG. 2 shows a wirebondable substrate structure having a tin or tin alloy layer, and FIG. 3 shows another structure having an additional barrier layer.

It should be understood that microelectronic device package 100 and/or package substrate 110 may have other configurations and/or be made of other materials in other embodiments. For example, in some cases, a single microelectronic device package may include any number of semiconductor dies disposed in a side-by-side configuration and/or stacked on top of one another. Also, in some embodiments, package substrate 110 may include or be replaced by a silicon interposer, ceramic substrate, lead frame, or the like.

FIG. 2 is a cross-sectional view of an example of tin-based, wirebond structure 200 according to some embodiments. Structure 200 includes tin-based bond pad surface layer 106 overlaid upon a portion of a base or metal layer that is part of (or coupled to) conductive interconnect 108. Also shown are wire 105, soldermask 107, and substrate dielectric 101. In some embodiments, base metal layer 108 may be a layer of conductive material, such as a copper layer, having a thickness of approximately 8 μm to 30 μm, depending upon the application. In other embodiments, however, base metal layer 108 may have other thicknesses and be made of other materials (e.g., gold, molybdenum (Mo), tungsten (W), aluminum, etc.). For example, in some cases, base metal layer 108 may be part of a lead frame and may include copper or other suitable conductive material.

An electrical coupling between wire 105 and base metal layer 108 enables an electrical signal to travel between semiconductor die 102 and elements external to microelectronic device package 100. To that end, tin-based bond pad surface layer 106 is formed over a portion of base metal 108 prior to bonding wire 105.

In an embodiment, a wirebond may be created by using tin-based bond pad surface layer 106 comprising elemental Sn having a thickness of less than 1.5 μm. In some cases, the thickness of layer 106 may be between 0.8 μm and 1.2 μm.

In order to create a good bond between wire 105 and surface material 106, in some embodiments, the latter has a sufficient hardness such that it can at least partially resist the forces applied during wirebonding, during which sufficient heat and inter-diffusion is generated to create a metallurgical bond. However, elemental tin is a relatively soft material with a hardness of about 4 HB at room temperature (25° C.) in the Brinell scale. Thick layers of elemental tin (e.g., 2 μm or greater) are not reliably bondable because Sn deforms easily, and sufficient heat and inter-diffusion are not formed. If, however, tin-based bond pad surface material 106 has a thickness of less than 1.5 μm, the force created by scrubbing surface material 106 between wire 105 and base metal 108 creates sufficient heat and inter-diffusion (some atoms from the wire 105 diffuse into base metal 108 and/or some atoms from base metal 108 diffuse into the wire 105) to form a suitable bond.

When wire 105 is made of copper, the bond is characterized by the formation of Cu—Sn intermetallic compounds (IMC) at the interface between wire 105 and tin-based bond pad surface layer 106 (not shown). Also, another IMC layer 201 may be formed between base metal layer 108 and tin-based bond pad surface layer 106. Particularly, these IMC formations may be created by a diffusion process that is driven by heat during fabrication, whereby atoms of tin from surface layer 106 penetrate base metal layer 108 (and wire 105), and atoms of copper (from wire 105 and from base metal layer 108) penetrate tin-based bond pad surface layer 106, thus creating crystal structures that can grow over time. Examples of such IMC formations include, but are not limited to, Cu₆Sn₅ and Cu₃Sn. As the wirebond ages, IMC layer 201 as well as IMC formations between wire 105 and surface layer 106 may grow such that they consume the tin of layer 106, and such that tin-based bond pad surface layer 106 may no longer exist in wirebond structure 200.

In another embodiment, tin-based bond pad surface layer 106 may include a tin alloy, where Sn is mixed with one or more additional elements. Examples of such additional materials include, but are not limited to, nickel (Ni), titanium (Ti), copper (Cu), silver (Ag), palladium (Pd), iron (Fe), cobalt (Co), cadmium (Cd), manganese (Mn), gold (Au), chromium (Cr), aluminum (Al), and/or antimony (Sb). In some embodiments, the percentage of elemental tin in the alloy by weight may be in the range of 85% or greater, wherein the non-tin materials may make up the remaining amount.

In some implementations, the tin alloy may have a solidus point that is higher than the wire bonding temperature, which is typically 175° C. in some embodiments. For example, nickel, titanium, copper, silver, palladium, iron, cobalt, manganese, gold, chromium, and/or antimony may each form alloys with tin that maintain a solidus point (i.e., a temperature below which a given substance is completely solid) as well as a liquidus point (i.e., the maximum temperature at which crystals can co-exist with the melt in thermodynamic equilibrium) well above 200° C.

In some implementations, the non-tin component may be in the range of 10% or less of the actual weight of the alloy. Adding any of the foregoing non-tin elements may increase the alloy's hardness, improving the bondability since heat generation and inter-diffusion are increased during bonding. For example hardness at room temperatures (25° C.) of Sn-3.5% Ag is Brinell 15 HB, Sn-0.7% Cu is 9 HB, and Sn-5% Sb is 13 HB. In some cases, the tin alloy may include a combination of non-tin elements. In that regard, examples of tin-based alloys that may be used in tin-based bond pad surface layer 106 (in contrast with elemental tin, gold, and copper) are summarized in Table I below:

TABLE I

| | Weight % | Weight % | Solidus/Liquidus | Hardness |
|---|---|---|---|---|
| Material (%) | Element 1 | Element 2 | (° C.) | (HB) |
| Sn100 | Sn - 100% | — | 232/232 | 4 |
| Au100 | Au - 100% | — | 1064/1064 | 25 |
| Cu100 | Cu - 100% | — | 1085/1085 | 35 |
| Sn96.5Ag3.5 | Sn - 96.5% | Ag - 3.5% | 221/221 | 15 |
| Sn95Ag05 | Sn - 95% | Ag - 5% | 221/240 | 14 |
| Sn99.3Cu0.7 | Sn - 99.3% | Cu - 0.7% | 227/227 | 9 |
| Sn95Sb05 | Sn - 95% | Sb - 5% | 232/240 | 13 |
| Sn91Sb09 | Sn - 91% | Sb - 9% | 245/245 | 23 |

Referring to Table I, it is noted that elemental tin has a hardness of 4HB, elemental copper has a hardness of 35 HB, and elemental gold has a hardness of 25 HB. Meanwhile, the examples of tin alloys in provided above have hardness values that are at least two times greater than that of pure tin, with Sn96.5Ag3.5 (15HB) approaching the properties of pure gold (25 HB). Generally speaking, alloying tin with a harder element may increase the hardness of the resulting alloy.

Thus, in some embodiments, tin-based bond pad surface layer 106 may be a tin alloy that has a Brinell hardness greater than 8 HB, or between 8.0 HB and 30 HB. Thus, in some embodiments, the layer 106 is a layer that that has a tin contact in the range of 85% or greater and has a hardness content of 8 HB or greater. With these hardness characteristics, tin-based bond pad surface layer 106 is able to sufficiently resist forces applied during bonding to generate sufficient heat and inter-diffusion to create a suitable metallurgical bond.

In some embodiments, in contrast with embodiments where tin-based bond pad surface layer 106 is made of elemental tin (and therefore its thickness is kept below 1.5 μm), the thickness of the tin alloy layer maybe greater than 1.5 μm. For example, in some cases, when a tin alloy is used in tin-based bond pad surface layer 106, layer 106 may have a thickness in the range of 0.3 μm to 5 μm.

FIG. 3 is a cross-sectional view of an example of another tin-based, wirebond structure 300 according to some embodiments. As previously noted, as package substrate 110 ages, tin-based bond pad surface layer 106 combines with base metal layer 108 to form an IMC layer that grows over time. This phenomenon may not present a problem after wire bonding between wire 105 and tin-based bond pad surface layer 106. However, it some, it may shorten the shelf life of package substrate 110, because once the entire tin-based material of layer 106 is diffused into layer 108, the resulting structure may no longer be bondable to wire 105. To address these, and other concerns, barrier layer 301 may be formed between tin-based bond pad surface layer 106 and base metal layer 108. In some cases, barrier layer 301 may include nickel, and Sn—Ni IMC layer is shown as layer 302.

In some embodiments, barrier layer 301 may include nickel and may have a thickness in the range of 2 μm to 20 μm. In other applications (e.g., interposer), however, barrier layer 301 may use other metals such as Ni, Pd, tantalum (Ta), TaNi, etc., which may have a thickness in the range of 0.01 μm to 0.5 μm.

At room temperature, an IMC layer formed at the boundary between a layer of elemental tin and a layer of elemental copper grows from 0 to about 0.6 μm in one year, and from 0 to about 0.8 in two years. Conversely, IMC layer 302 formed at the boundary between a layer of elemental tin and a layer of elemental nickel grows from 0 to about 0.06 μm in one year, and from 0 to about 0.08 in two years. Accordingly, in some cases, the presence of barrier layer 301 may increase the shelf life (i.e., the length of time it can be stored before wire bonding) of a substrate package having a tin-based wirebondable substrate structure by approximately a factor of 10.

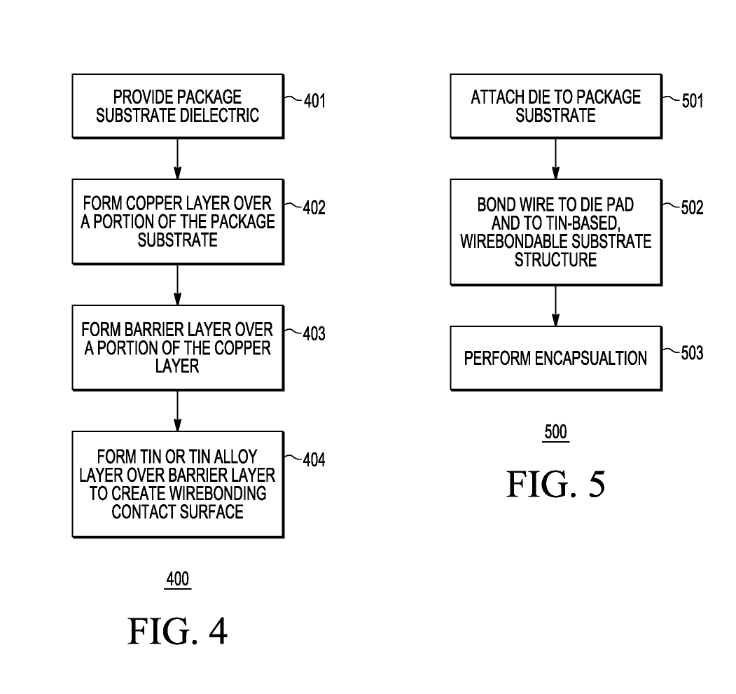

FIG. 4 is a flowchart of method 400 for fabricating a tin-based, wirebond structure according to some embodiments. At block 401, method 400 includes providing a package substrate dielectric such as, for example, substrate dielectric 101 in FIG. 1. At block 402, method 400 includes forming a copper layer (or other base metal layer) over a portion of the package substrate dielectric, for example, as part of conductive interconnect 108. At block 403, method 400 includes forming a barrier layer (e.g., nickel) over a portion of the copper layer, for example, such as barrier layer 301 of FIG. 3. In some cases, the barrier layer may be barrier layer 301 may have a thickness in the range of 2 μm to 20 μm.

Then, at block 404, method 400 includes forming a tin or tin alloy layer over the barrier layer to create a tin-based, wirebondable contact surface. As noted above, in some cases, the tin or tin alloy layer may have a thickness of 1.5 μm or less and/or a hardness greater than 8.0 HB. However, in other embodiments, the thickness of the layer of tin may be greater than 1.5 and/or the hardness may be less.

In some cases, a deposition process that that plates, grows, coats, or otherwise transfers a material onto a surface may be used to from one layer over another (e.g., to form tin-based bond pad surface layer 106 over a portion of base metal layer 108). Available deposition technologies include Physical Vapor Deposition (PVD), Chemical Vapor Deposition (CVD), Electrolytic Plating or Electrochemical Deposition (ECD), Electroless Plating, or the like. Electroless Plating techniques such as auto-catalytic or immersion may be used to deposit tin in order to form bond pad surface layer 106 over base metal layer 108. Additionally or alternatively, Electroless Plating or other suitable chemical techniques may be used to deposit barrier layer 301 upon metal base layer 108. It should be understood that each deposition process may itself involve a plurality of sub-processes, such as, for example, patterning (i.e., lithography), etching or removal, etc.

Also, it should be noted that method 400 is provided for sake of illustration only. In various embodiments, numerous variations may be implemented. For example, one or more operations may be performed prior to block 401 and/or after block 404. Moreover, certain operations may be combined, new operations may be added, or one or more operations may be removed. For instance, as described above, in some implementations, method 400 may skip block 403 and forego formation of a barrier layer.

FIG. 5 is a flowchart of method 500 for manufacturing a microelectronic device package according to some embodiments. At block 501, method 500 includes attaching a semiconductor die to a package substrate, for example, with a layer of adhesive or tape. At block 502, wires are wirebonded to terminals on the semiconductor die and to corresponding tin-based wirebond structures formed on the package substrate, for example, using method 400 of FIG. 4. In some implementations, a thermosonic wirebonding process may be used where 50-120 mA of ultrasonic power and 20-50 grams of force at 175° C. are applied to the wire and to the substrate structure. In other implementations, however, any other suitable amount of heat, pressure, and/or ultrasonic energy may be used as part of a wirebonding process. For example, in some cases, a wedge bonding process may be used. Then, at block 503, the die and substrate are encapsulated with an encapsulant (e.g., an epoxy or mold compound).

In many implementations, the systems and methods disclosed herein may be incorporated into a wide range of electronic devices including, for example, computer systems or Information Technology (IT) products such as servers, desktops, laptops, memories, switches, routers, etc.; telecommunications hardware; consumer devices or appliances such as mobile phones, tablets, television sets, cameras, sound systems, etc.; scientific instrumentation; industrial robotics; medical or laboratory electronics such as imaging, diagnostic, or therapeutic equipment, etc.; transportation vehicles such as automobiles, buses, trucks, trains, watercraft, aircraft, etc.; military equipment, etc. More generally, these systems and methods may be incorporated into any device or system having one or more electronic parts or components.

Turning to FIG. 6, a block diagram of electronic device 600 is depicted. In some embodiments, electronic device 600 may be any of the aforementioned electronic devices, or any other electronic device. As illustrated, electronic device 600 includes one or more Printed Circuit Boards (PCBs) 601, and at least one of PCBs 601 includes one or more microelectronic device packages(s) 602. In some implementations, device package(s) 602 may include one or more tin-based, wirebond structures as described above.

Examples of device package(s) 602 may include, for instance, a System-On-Chip (SoC), an Application Specific Integrated Circuit (ASIC), a Digital Signal Processor (DSP), a Field-Programmable Gate Array (FPGA), a processor, a microprocessor, a controller, a microcontroller (MCU), a Graphics Processing Unit (GPU), or the like. Additionally or alternatively, device package(s) 602 may include a memory circuit or device such as, for example, a Random Access Memory (RAM), a Static RAM (SRAM), a Magnetoresistive RAM (MRAM), a Nonvolatile RAM (NVRAM, such as “FLASH” memory, etc.), and/or a Dynamic RAM (DRAM) such as Synchronous DRAM (SDRAM), a Double Data Rate RAM, an Erasable Programmable ROM (EPROM), an Electrically Erasable Programmable ROM (EEPROM), etc. Additionally or alternatively, device package(s) 602 may include one or more mixed-signal or analog circuits, such as, for example, Analog-to-Digital Converter (ADCs), Digital-to-Analog Converter (DACs), Phased Locked Loop (PLLs), oscillators, filters, amplifiers, etc. Additionally or alternatively, device package(s) 602 may include one or more Micro-ElectroMechanical Systems (MEMS), Nano-ElectroMechanical Systems (NEMS), or the like.

Generally speaking, device package(s) 602 may be configured to be mounted onto PCB 601 using any suitable packaging technology such as, for example, Ball Grid Array (BGA) packaging or the like. In some applications, PCB 601 may be mechanically mounted within or fastened onto electronic device 600. It should be noted that, in certain implementations, PCB 601 may take a variety of forms and/or may include a plurality of other elements or components in addition to device package(s) 602. It should also be noted that, in some embodiments, PCB 601 may not be used and/or device package(s) 602 may assume any other suitable form(s).

As discussed herein, in an illustrative, non-limiting embodiment, a wirebond structure may include a conductive layer and a layer of tin located over a portion of the conductive layer, where the layer of tin provides a wirebonding contact surface configured to receive a bond wire, and where the layer of tin has a thickness of 1.5 μm or less. In some implementations, the tin may be characterized as elemental tin. For example, the layer of tin may have a thickness between 0.8 and 1.2 μm, the layer of tin may have a hardness of 8.0 HB or more at room temperature, and/or the layer of tin may have a hardness between 8.0 HB and 30 HB at room temperature. In other implementations, the layer of tin may include a tin alloy. For example, the tin alloy may include at least 85% tin by weight, the tin alloy may include at least one element selected from the group consisting of: nickel, titanium, copper, silver, palladium, iron, cobalt, zinc, manganese, gold, and antimony, and/or the tin alloy may have a solidus temperature and a liquidus temperature above a wire bonding temperature. Additionally or alternatively, the wirebond structure may include a layer of IMC between the conductive layer and the layer of tin. Additionally or alternatively, the wirebond structure may include a barrier layer between the conductive layer and the layer of tin. For example, the barrier layer may be configured to reduce growth of IMC between the conductive layer and the layer of tin. The barrier layer may also include at least one of: nickel, palladium, or tantalum. Moreover, the wirebond structure may be characterized as a substrate bond pad.

In another illustrative, non-limiting embodiment, a wirebond structure may include a conductive layer and a layer of tin located over a portion of the conductive layer, where the layer of tin provides a wirebonding contact surface configured to receive a bond wire, and where the layer of tin has a hardness of 8.0 HB or more at room temperature. For example, the layer of tin may have a hardness between 8.0 HB and 30 HB at room temperature. In some implementations, the tin may be characterized as elemental tin. The layer of tin may have a thickness of 1.5 μm or less and/or the layer of tin may have a thickness between 0.8 and 1.2 μm. In other implementations, the layer of tin may include a tin alloy. The tin alloy may include at least 85% tin by weight, the tin alloy may include at least one element selected from the group consisting of: nickel, titanium, copper, silver, palladium, iron, cobalt, zinc, manganese, gold, and antimony, and/or the tin alloy may have a solidus temperature and a liquidus temperature above a wire bonding temperature. Additionally or alternatively, the wirebond structure may include a layer of IMC between the conductive layer and the layer of tin. Additionally or alternatively, the wirebond structure may include a barrier layer between the conductive layer and the layer of tin. For example, the barrier layer may be configured to reduce growth of IMC between the conductive layer and the layer of tin. The barrier layer may also include at least one of: nickel, palladium, or tantalum. Moreover, the wirebond structure may be characterized as a substrate bond pad.

In yet another illustrative, non-limiting embodiment, a wirebond structure may include a conductive layer and a layer of tin alloy located over a portion of the conductive layer, where the layer of tin alloy provides a wirebonding contact surface configured to receive a bond wire. In some implementations, the layer of tin alloy may include at least 85% tin by weight, the layer of tin alloy may include at least one element selected from the group consisting of: nickel, titanium, copper, silver, palladium, iron, cobalt, zinc, manganese, gold, and antimony, the layer of tin alloy may have a solidus temperature and a liquidus temperature above a wire bonding temperature, the layer of tin alloy may have a thickness of 1.5 μm or less, the layer of tin alloy may have a thickness between 0.8 and 1.2 μm, the layer of tin alloy may have a hardness of 8.0 HB or more at room temperature, and/or the layer of tin alloy may have a hardness between 8.0 HB and 30 HB at room temperature. Additionally or alternatively, the wirebond structure may include a layer of IMC between the conductive layer and the layer of tin alloy. Additionally or alternatively, the wirebond structure may include a barrier layer between the conductive layer and the layer of tin alloy. For example, the barrier layer may be configured to reduce growth of IMC between the conductive layer and the layer of tin alloy. The barrier layer may also include at least one of: nickel, palladium, or tantalum. Moreover, the wirebond structure may be characterized as a substrate bond pad.

In still another illustrative, non-limiting embodiment, an electronic package may include a semiconductor die located over a substrate, the substrate including a wirebondable structure, the wirebondable structure including: a dielectric layer; a conductive layer located over a portion of the dielectric layer; and a layer of tin located over a portion of the conductive layer, the layer of tin configured to provide a wirebonding contact surface, the layer of tin having a thickness of 1.5 μm or less. In some implementations, the layer of tin may be characterized as elemental tin. The layer of tin may have a thickness between 0.8 and 1.2 μm, the layer of tin may have a hardness of 8.0 HB or more at room temperature, and/or the layer of tin may have a hardness between 8.0 HB and 30 HB at room temperature. In other implementations, the layer of tin may include a tin alloy. The tin alloy may include at least 85% tin by weight, the tin alloy may include at least one element selected from the group consisting of: nickel, titanium, copper, silver, palladium, iron, cobalt, zinc, manganese, gold, and antimony, and/or the tin alloy may have a solidus temperature and a liquidus temperature above a wire bonding temperature. Additionally or alternatively, the wirebondable structure may include a layer of IMC between the conductive layer and the layer of tin. Additionally or alternatively, the wirebondable structure may include a barrier layer between the conductive layer and the layer of tin. For example, the barrier layer may be configured to reduce growth of IMC between the conductive layer and the layer of tin. The barrier layer may also include at least one of: nickel, palladium, or tantalum. Moreover, the wirebondable structure may be characterized as a substrate bond pad.

In yet another embodiment, an electronic package may include a semiconductor die located over a substrate, the substrate including a wirebondable structure, the wirebondable structure including: a dielectric layer; a conductive layer located over a portion of the dielectric layer; and a layer of tin located over a portion of the conductive layer, the layer of tin configured to provide a wirebonding contact surface, the layer of tin having a hardness of 8 HB or more at room temperature. For example, the layer of tin may have a hardness between 8.0 HB and 30 HB at room temperature. In some implementations, the tin may be characterized as elemental tin. The layer of tin may have a thickness of 1.5 μm or less and/or the layer of tin may have a thickness between 0.8 and 1.2 μm. In other implementations, the layer of tin may include a tin alloy, the tin alloy may include at least 85% tin by weight, the tin alloy may include at least one element selected from the group consisting of: nickel, titanium, copper, silver, palladium, iron, cobalt, zinc, manganese, gold, and antimony, and/or the tin alloy may have a solidus temperature and a liquidus temperature above a wire bonding temperature. Additionally or alternatively, the wirebondable structure may include a layer of IMC between the conductive layer and the layer of tin. Additionally or alternatively, the wirebondable structure may include a barrier layer between the conductive layer and the layer of tin. For example, the barrier layer may be configured to reduce growth of IMC between the conductive layer and the layer of tin. The barrier layer may also include at least one of: nickel, palladium, or tantalum. Moreover, the wirebondable structure may be characterized as a substrate bond pad.

In still another illustrative, non-limiting embodiment, an electronic package may include a semiconductor die located over a substrate, the substrate including a wirebondable structure, the wirebondable structure including: a dielectric layer; a conductive layer located over a portion of the dielectric layer; and a layer of tin alloy located over a portion of the conductive layer, the layer of tin alloy configured to provide a wirebonding contact surface. The layer of tin alloy may include at least 85% tin by weight, the layer of tin alloy may include at least one element selected from the group consisting of: nickel, titanium, copper, silver, palladium, iron, cobalt, zinc, manganese, gold, and antimony, the layer of tin alloy may have a solidus temperature and a liquidus temperature above a wire bonding temperature, the layer of tin alloy may have a thickness of 1.5 μm or less, the layer of tin alloy may have a thickness between 0.8 and 1.2 μm, the layer of tin alloy may have a hardness of 8.0 HB or more at room temperature, and/or the layer of tin alloy may have a hardness between 8.0 HB and 30 HB at room temperature. Additionally or alternatively, the wirebondable structure may include a layer of IMC between the conductive layer and the layer of tin alloy. Additionally or alternatively, the wirebondable structure may include a barrier layer between the conductive layer and the layer of tin alloy. For example, the barrier layer may be configured to reduce growth of IMC between the conductive layer and the layer of tin alloy. The barrier layer may also include at least one of: nickel, palladium, or tantalum. Moreover, the wirebondable structure may be characterized as a substrate bond pad.

In yet another illustrative, non-limiting embodiment, an electronic package may include a semiconductor die located over a substrate; and a wire configured to couple a terminal of the semiconductor die to a bond pad on the substrate, where a wire bond between the wire and the bond pad includes an amount of tin originated from a layer of tin formed on the bond pad, the layer of tin having a thickness of 1.5 μm or less. In some implementations, the tin may be characterized as elemental tin. The layer of tin may have a hardness of 8.0 HB or more at room temperature and/or the layer of tin may have a hardness between 8.0 HB and 30 HB at room temperature. In another implementation, the layer of tin may include a tin alloy. The tin alloy may include at least 85% tin by weight, the tin alloy may include at least one element selected from the group consisting of: nickel, titanium, copper, silver, palladium, iron, cobalt, zinc, manganese, gold, and antimony, and/or the tin alloy may have a solidus temperature and a liquidus temperature above a wire bonding temperature. Additionally or alternatively, the semiconductor die may include a layer of IMC between the conductive layer and the layer of tin. Additionally or alternatively, the semiconductor die may include a barrier layer between the conductive layer and the layer of tin. For example, the barrier layer may be configured to reduce growth of IMC between the conductive layer and the layer of tin. The barrier layer may also include at least one of: nickel, palladium, or tantalum.

In still another embodiment, an electronic package may include a semiconductor die located over a substrate; and a wire configured to couple a terminal of the semiconductor die to a bond pad on the substrate, where a wire bond between the wire and the bond pad includes an amount of tin originated from a layer of tin formed on the bond pad, the layer of tin having a hardness of 8 HB or more at room temperature. For example, the layer of tin may have a hardness between 8.0 HB and 30 HB at room temperature. In some implementations, the tin may be characterized as elemental tin. The layer of tin may have a thickness of 1.5 μm or less and/or the layer of tin may have a thickness between 0.8 and 1.2 μm. In another implementation, the layer of tin may include a tin alloy. The tin alloy may include at least 85% tin by weight, the tin alloy may include at least one element selected from the group consisting of: nickel, titanium, copper, silver, palladium, iron, cobalt, zinc, manganese, gold, and antimony, and/or the tin alloy may have a solidus temperature and a liquidus temperature above a wire bonding temperature. Additionally or alternatively, the semiconductor die may include a layer of IMC between the conductive layer and the layer of tin. Additionally or alternatively, the semiconductor die may include a barrier layer between the conductive layer and the layer of tin. For example, the barrier layer may be configured to reduce growth of IMC between the conductive layer and the layer of tin. The barrier layer may also include at least one of: nickel, palladium, or tantalum.

In yet another embodiment, an electronic package may include a semiconductor die located over a substrate; and a wire configured to couple a terminal of the semiconductor die to a bond pad on the substrate, where a wire bond between the wire and the bond pad includes an amount of tin originated from a layer of tin alloy formed on the bond pad. In some implementations, the layer of tin alloy may include at least 85% tin by weight, the layer of tin alloy may include at least one element selected from the group consisting of: nickel, titanium, copper, silver, palladium, iron, cobalt, zinc, manganese, gold, and antimony, the layer of tin alloy may have a solidus temperature and a liquidus temperature above a wire bonding temperature, the layer of tin alloy may have a thickness of 1.5 μm or less, the layer of tin alloy may have a thickness between 0.8 and 1.2 μm, the layer of tin alloy may have a hardness of 8.0 HB or more at room temperature, and/or the layer of tin alloy may have a hardness between 8.0 HB and 30 HB at room temperature. Additionally or alternatively, the semiconductor die may include a layer of IMC between the conductive layer and the layer of tin alloy. Additionally or alternatively, the semiconductor die may include a barrier layer between the conductive layer and the layer of tin alloy. For example, the barrier layer may be configured to reduce growth of IMC between the conductive layer and the layer of tin alloy. The barrier layer may also include at least one of: nickel, palladium, or tantalum.

In still another embodiment, a method for creating a wirebond structure may include forming a conductive layer over a portion of a package substrate; and forming a layer of tin over a portion of the conductive layer, the layer of tin configured to provide a wirebonding contact surface, the layer of tin having a thickness of 1.5 μm or less. In some implementations, the tin may be characterized as elemental tin, the layer of tin may have a thickness between 0.8 and 1.2 μm, the layer of tin may have a hardness of 8.0 HB or more at room temperature, and/or the layer of tin may have a hardness between 8.0 HB and 30 HB at room temperature. In other implementations, the layer of tin may include a tin alloy, the tin alloy may include at least 85% tin by weight, the tin alloy may include at least one element selected from the group consisting of: nickel, titanium, copper, silver, palladium, iron, cobalt, zinc, manganese, gold, and antimony, and/or the tin alloy may have a solidus temperature and a liquidus temperature above a wire bonding temperature. Additionally or alternatively, the wirebond structure may include a layer of IMC between the conductive layer and the layer of tin. Additionally or alternatively, the wirebond structure may include a barrier layer between the conductive layer and the layer of tin. For example, the barrier layer may be configured to reduce growth of IMC between the conductive layer and the layer of tin. The barrier layer may also include at least one of: nickel, palladium, or tantalum. Moreover, the wirebond structure may be characterized as a substrate bond pad.

In yet another embodiment, a method for creating a wirebond structure may include forming a conductive layer over a portion of a package substrate; and forming a layer of tin over a portion of the conductive layer, the layer of tin configured to provide a wirebonding contact surface, the layer of tin having a hardness of 8 HB or more at room temperature. For example, the layer of tin may have a hardness between 8.0 HB and 30 HB at room temperature. In some implementations, the tin may be characterized as elemental tin. The layer of tin may have a thickness of 1.5 μm or less and/or the layer of tin may have a thickness between 0.8 and 1.2 μm. In other implementations, the layer of tin may include a tin alloy. The tin alloy may include at least 85% tin by weight, the tin alloy may include at least one element selected from the group consisting of: nickel, titanium, copper, silver, palladium, iron, cobalt, zinc, manganese, gold, and antimony, and/or the tin alloy may have a solidus temperature and a liquidus temperature above a wire bonding temperature. Additionally or alternatively, the wirebond structure may include a layer of IMC between the conductive layer and the layer of tin. Additionally or alternatively, the wirebond structure may include a barrier layer between the conductive layer and the layer of tin. For example, the barrier layer may be configured to reduce growth of IMC between the conductive layer and the layer of tin. The barrier layer may also include at least one of: nickel, palladium, or tantalum. Moreover, the wirebond structure may be characterized as a substrate bond pad.

In still another embodiment, a method for creating a wirebond structure may include forming a conductive layer over a portion of a package substrate; and forming a layer of tin alloy over a portion of the conductive layer, the layer of tin alloy configured to provide a wirebonding contact surface. In some implementations, the layer of tin alloy may include at least 85% tin by weight, the layer of tin alloy may include at least one element selected from the group consisting of: nickel, titanium, copper, silver, palladium, iron, cobalt, zinc, manganese, gold, and antimony, the layer of tin alloy may have a solidus temperature and a liquidus temperature above a wire bonding temperature, the layer of tin alloy may have a thickness of 1.5 μm or less, the layer of tin alloy may have a thickness between 0.8 and 1.2 μm, the layer of tin alloy may have a hardness of 8.0 HB or more at room temperature, and/or the layer of tin alloy may have a hardness between 8.0 HB and 30 HB at room temperature. Additionally or alternatively, the wirebond structure may include a layer of IMC between the conductive layer and the layer of tin alloy. Additionally or alternatively, the wirebond structure may include a barrier layer between the conductive layer and the layer of tin alloy. For example, the barrier layer may be configured to reduce growth of IMC between the conductive layer and the layer of tin alloy. The barrier layer may also include at least one of: nickel, palladium, or tantalum. Moreover, the wirebond structure may be characterized as a substrate bond pad.

In yet another embodiment, a method may include wirebonding a contact structure of a package substrate using a wire, the structure including: a conductive layer; and a layer of tin located over a portion of the conductive layer, the layer of tin having a thickness of 1.5 μm or less. In some implementations, the tin may be characterized as elemental tin. The layer of tin may have a thickness between 0.8 and 1.2 μm, the layer of tin may have a hardness of 8.0 HB or more at room temperature, and/or the layer of tin may have a hardness between 8.0 HB and 30 HB at room temperature. In other implementations, the layer of tin may include a tin alloy. The tin alloy may include at least 85% tin by weight, the tin alloy may include at least one element selected from the group consisting of: nickel, titanium, copper, silver, palladium, iron, cobalt, zinc, manganese, gold, and antimony, and/or the tin alloy may have a solidus temperature and a liquidus temperature above a wire bonding temperature. Additionally or alternatively, the wirebond structure may include a layer of IMC between the conductive layer and the layer of tin. Additionally or alternatively, the wirebond structure may include a barrier layer between the conductive layer and the layer of tin. For example, the barrier layer may be configured to reduce growth of IMC between the conductive layer and the layer of tin. The barrier layer may also include at least one of: nickel, palladium, or tantalum. The wire may include at least one element selected from the group consisting of: copper, gold, silver, and aluminum. Moreover, the conductive layer may include copper. The method may also include wirebonding the wire to a terminal of a semiconductor die. The method may further include encapsulating the wire and the semiconductor die.

In still another embodiment, a method may include wirebonding a contact structure of a package substrate using a wire a conductive layer; and a layer of tin located over a portion of the conductive layer, the layer of tin having a hardness of 8 HB or more at room temperature. For example, the layer of tin may have a hardness between 8.0 HB and 30 HB at room temperature. In some implementations, the tin may be characterized as elemental tin. The layer of tin may have a thickness of 1.5 μm or less and/or the layer of tin may have a thickness between 0.8 and 1.2 μm. In other implementations, the layer of tin may include a tin alloy. The tin alloy may include at least 85% tin by weight, the tin alloy may include at least one element selected from the group consisting of: nickel, titanium, copper, silver, palladium, iron, cobalt, zinc, manganese, gold, and antimony, and/or the tin alloy may have a solidus temperature and a liquidus temperature above a wire bonding temperature. Additionally or alternatively, the wirebond structure may include a layer of IMC between the conductive layer and the layer of tin. Additionally or alternatively, the wirebond structure may include a barrier layer between the conductive layer and the layer of tin. For example, the barrier layer may be configured to reduce growth of IMC between the conductive layer and the layer of tin. The barrier layer may also include at least one of: nickel, palladium, or tantalum. The wire may include at least one element selected from the group consisting of: copper, gold, silver, and aluminum. Moreover, the conductive layer may include copper. The method may also include wirebonding the wire to a terminal of a semiconductor die. The method may further include encapsulating the wire and the semiconductor die.

In still another embodiment, a method may include wirebonding a contact structure of a package substrate using a wire, the structure including: a conductive layer; and a layer of tin alloy located over a portion of the conductive layer. The layer of tin alloy may include at least 85% tin by weight, the layer of tin alloy may include at least one element selected from the group consisting of: nickel, titanium, copper, silver, palladium, iron, cobalt, zinc, manganese, gold, and antimony, the layer of tin alloy may have a solidus temperature and a liquidus temperature above a wire bonding temperature, the layer of tin alloy may have a thickness of 1.5 μm or less, the layer of tin alloy may have a thickness between 0.8 and 1.2 μm, the layer of tin alloy may have a hardness of 8.0 HB or more at room temperature, and/or the layer of tin alloy may have a hardness between 8.0 HB and 30 HB at room temperature. Additionally or alternatively, the wirebond structure may include a layer of IMC between the conductive layer and the layer of tin alloy. Additionally or alternatively, the wirebond structure may include a barrier layer between the conductive layer and the layer of tin alloy. For example, the barrier layer may be configured to reduce growth of IMC between the conductive layer and the layer of tin alloy. The barrier layer may also include at least one of: nickel, palladium, or tantalum. The wire may include at least one element selected from the group consisting of: copper, gold, silver, and aluminum. Moreover, the conductive layer may include copper. The method may also include wirebonding the wire to a terminal of a semiconductor die. The method may further include encapsulating the wire and the semiconductor die.

Although the invention(s) is/are described herein with reference to specific embodiments, various modifications and changes can be made without departing from the scope of the present invention(s), as set forth in the claims below. Accordingly, the specification and figures are to be regarded in an illustrative rather than a restrictive sense, and all such modifications are intended to be included within the scope of the present invention(s). Any benefits, advantages, or solutions to problems that are described herein with regard to specific embodiments are not intended to be construed as a critical, required, or essential feature or element of any or all the claims.

Unless stated otherwise, terms such as “first” and “second” are used to arbitrarily distinguish between the elements such terms describe. Thus, these terms are not necessarily intended to indicate temporal or other prioritization of such elements. The terms “coupled” or “operably coupled” are defined as connected, although not necessarily directly, and not necessarily mechanically. The terms “a” and “an” are defined as one or more unless stated otherwise. The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system, device, or apparatus that “comprises,” “has,” “includes” or “contains” one or more elements possesses those one or more elements but is not limited to possessing only those one or more elements. Similarly, a method or process that “comprises,” “has,” “includes” or “contains” one or more operations possesses those one or more operations but is not limited to possessing only those one or more operations.

1. An electronic package, comprising:
a semiconductor die located over a substrate; and
a wire configured to couple a terminal of the semiconductor die to a bond pad on the substrate, wherein a wire bond between the wire and the bond pad includes an amount of tin originated from a layer of tin alloy formed on the bond pad.

2. The electronic package of claim 1, wherein the layer of tin alloy includes at least 85% tin by weight.

3. The electronic package of claim 1, wherein the layer of tin alloy includes at least one element selected from the group consisting of: nickel, titanium, copper, silver, palladium, iron, cobalt, cadmium, zinc, manganese, gold, aluminum, and antimony.

4. The electronic package of claim 1, wherein the layer of tin alloy has a solidus temperature and a liquidus temperature above a wire bonding temperature.

5. The electronic package of claim 1, wherein the layer of tin alloy has a thickness of 1.5 μm or less.

6. The electronic package of claim 5, wherein the layer of tin alloy has a thickness between 0.8 and 1.2 μm.

7. The electronic package of claim 1, wherein the layer of tin alloy has a hardness of 8.0 HB or more at room temperature.

8. The electronic package of claim 7, wherein the layer of tin alloy has a hardness between 8.0 HB and 30 HB at room temperature.

9. The electronic package of claim 1, further comprising a layer of intermetallic compounds (IMC) between the conductive layer and the layer of tin alloy.

10. The electronic package of claim 1, further comprising a barrier layer between the conductive layer and the layer of tin alloy.

11. The electronic package of claim 1, wherein at least a portion of the layer of tin alloy remains over the bond pad at a location outside the area of the wirebond.

12. The electronic package of claim 1, wherein the bond pad includes copper.

13. A wirebond structure, comprising:
a conductive layer; and
a layer of tin alloy located over a portion of the conductive layer, wherein the layer of tin alloy provides a wirebonding contact surface configured to receive a bond wire.

14. The wirebond structure of claim 13, wherein the layer of tin alloy includes at least 85% tin by weight.

15. The wirebond structure of claim 13, wherein the layer of tin alloy has a thickness of 1.5 μm or less.

16. The wirebond structure of claim 13, wherein the layer of tin alloy has a hardness between 8.0 HB and 30 HB at room temperature.

17. The wirebond structure of claim 13, wherein the conductive layer is characterized as copper.

18. An electronic package, comprising:
a semiconductor die located over a substrate, the substrate including a wirebondable structure, the wirebondable structure including:
a dielectric layer;
a conductive layer located over a portion of the dielectric layer, wherein the conductive layer includes copper;
a layer of tin alloy located at least over a portion of the conductive layer; and
a wire configured to couple a terminal of the semiconductor die to a bond pad on the portion of the conductive layer, wherein a wire bond between the wire and the bond pad includes an amount of tin originated from the layer of tin alloy.

19. The electronic package of claim 18, wherein the layer of tin alloy includes at least one element selected from the group consisting of: nickel, titanium, copper, silver, palladium, iron, cobalt, cadmium, zinc, manganese, gold, aluminum, and antimony.

20. The electronic package of claim 18, wherein the layer of tin alloy has a hardness between 8.0 HB and 30 HB at room temperature.
